(19) United States
(12) Patent Application Publication
(10) Pub. No.: US 2026/0369511 A1
(43) Pub. Date: Nov. 19, 2026

(54) ELECTRON BEAM WRITING APPARATUS AND ELECTRON BEAM WRITING METHOD

(71) Applicant: NuFlare Technology, Inc., Yokohama-shi (JP)

(72) Inventors: Yasuharu SASAKI, Yokohama-shi (JP); Satoshi NAKAHASHI, Yokohama-shi (JP)

(73) Assignee: NuFlare Technology, Inc., Yokohama-shi (JP)

(21) Appl. No.: 19/743,755

(22) Filed: Jul. 16, 2026

Related U.S. Application Data
(63) Continuation of application No. PCT/JP2025/000600, filed on Feb. 21, 2025.

(30) Foreign Application Priority Data
May 23, 2024 (JP) 2024-084090

(51) Int. Cl. H01J 37/04; H01J 37/24; H01J 37/317

(52) U.S. Cl. CPC H01J 37/045; H01J 37/241; H01J 37/3174; H01J 2237/0435

(57) ABSTRACT

In one embodiment, an electron beam writing apparatus includes an emission unit configured to emit an electron beam, an aperture substrate having an opening through which the electron beam passes and configured to block a part of the electron beam, a deflector configured to deflect the electron beam having passed through the opening of the aperture substrate and to irradiate the electron beam onto a target substrate to write a pattern, a wiring connected to the aperture substrate, through which a current based on the part of the electron beam blocked by the aperture substrate flows, a ground potential supply unit connected to the wiring, and a voltage drop element connected in series in the wiring connecting the aperture substrate and the ground potential supply unit, the voltage drop element being configured to apply a negative potential to the aperture substrate.

### CROSS-REFERENCE TO RELATED APPLICATIONS

This application is a continuation of International Application No. PCT/JP2025/006000, filed on Feb. 21, 2025, which claims priority to Japanese Patent Application No. JP 2024-084090, filed on May 23, 2024, the contents of which are incorporated herein by reference.

### FIELD

The present invention relates to an electron beam writing apparatus and an electron beam writing method.

### BACKGROUND

With the increasing integration of LSIs, the circuit line widths required for semiconductor devices have been progressively reduced year by year. In order to form a desired circuit pattern on a semiconductor device, a method is employed in which a highly precise original pattern (a mask, or, particularly when used in a stepper or a scanner, also referred to as a reticle) formed on quartz is reduced and transferred onto a wafer using a reduction projection exposure apparatus. Such a highly precise original pattern is written by an electron beam writing apparatus, and so-called electron beam lithography technology is used.

As shown in FIG. 8, in an electron beam writing apparatus, an electron gun 200 is provided within an electron optical column 102 that is grounded. A high voltage is applied to the electron gun 200 using a high-voltage power supply P to emit an electron beam B, and the electron beam B is deflected by a deflector (not shown) to write a pattern on a sample S. The electron beam B emitted from the electron gun 200 passes through a plurality of aperture substrates AS provided in the electron optical column 102 and is irradiated onto the sample S. The plurality of aperture substrates AS include, for example, an aperture substrate for cutting the beam current to an appropriate level, an aperture substrate for cutting the electron beam B from the sample surface, an aperture substrate for monitoring the beam current, and an aperture substrate for shaping the beam. By passing through the plurality of aperture substrates AS, the beam current and beam shape of the electron beam B are adjusted.

Some of the plurality of aperture substrates AS constitute part of a beam current detection mechanism and are connected to a current detector 400 via a coaxial cable L. Electrons (electron beam B) emitted from the electron gun 200 and irradiated onto the sample S return to the high-voltage power supply P that supplies power to the electron gun 200 via the electron optical column 102. Electrons irradiated onto the aperture substrates AS also return to the high-voltage power supply P via the coaxial cable L, the current detector 400, the electron optical column 102, and the like.

The current detector 400 detects the beam current of the electron beam irradiated onto the aperture substrates AS. Based on the detection result of the current detector 400, fluctuations in the beam current and the presence or absence of discharge are monitored. The beam current detection mechanism (the current detector 400 and the aperture substrates AS) operates at or near a ground potential (0 V).

When the electron beam is irradiated onto the aperture substrates AS, secondary electrons including reflected electrons are generated, which may cause a problem in that the secondary electrons remaining on the beam trajectory can affect the trajectory of the electron beam B.

### REFERENCES

JP 5-174774 A
JP 2012-114127 A
JP 2009-70944 A

### SUMMARY

The present embodiment provides an electron beam writing apparatus and an electron beam writing method that can suppress an influence of secondary electrons on a beam trajectory while detecting a beam current using an aperture substrate.

In one embodiment, an electron beam writing apparatus includes an emission unit configured to emit an electron beam, an aperture substrate having an opening through which the electron beam passes and configured to block a part of the electron beam, a deflector configured to deflect the electron beam having passed through the opening of the aperture substrate and to irradiate the electron beam onto a target substrate to write a pattern, a wiring connected to the aperture substrate, through which a current based on the part of the electron beam blocked by the aperture substrate flows, a ground potential supply unit connected to the wiring, and a voltage drop element connected in series in the wiring connecting the aperture substrate and the ground potential supply unit, the voltage drop element being configured to apply a negative potential to the aperture substrate.

According to the present embodiment, it is possible to suppress an influence of secondary electrons on a beam trajectory while detecting a beam current using an aperture substrate.

### BRIEF DESCRIPTION OF DRAWINGS

FIG. 1 is a schematic configuration diagram of a writing apparatus according to an embodiment of the present invention.

FIG. 2 is a conceptual diagram showing a main deflection region and a sub-deflection region.

FIG. 3 is a diagram for explaining a voltage drop caused by a resistor.

FIG. 4A is a diagram showing an example of a voltage drop element.

FIG. 4B is a diagram showing an example of a voltage drop element.

FIG. 4C is a diagram showing an example of a voltage drop element.

FIG. 5 is a diagram showing a configuration for applying a negative potential to an aperture substrate according to a comparative example.

FIG. 6 is a diagram showing a beam current detection configuration according to a comparative example.

FIG. 7 is a diagram showing a beam current detection configuration according to the embodiment.

FIG. 8 is a diagram showing an example of a beam current detection configuration.

FIG. 9 is a schematic configuration diagram of a writing apparatus according to a modification.

FIG. 10A is a schematic configuration diagram of a writing apparatus according to a modification.

FIG. 10B is a schematic configuration diagram of a writing apparatus according to a modification.

FIG. 10C is a schematic configuration diagram of a writing apparatus according to a modification.

### DETAILED DESCRIPTION

Hereinafter, embodiments of the present invention will be described with reference to the drawings. In the embodiment, a variable-shaped writing apparatus 100 will be described as an example of an electron beam writing apparatus.

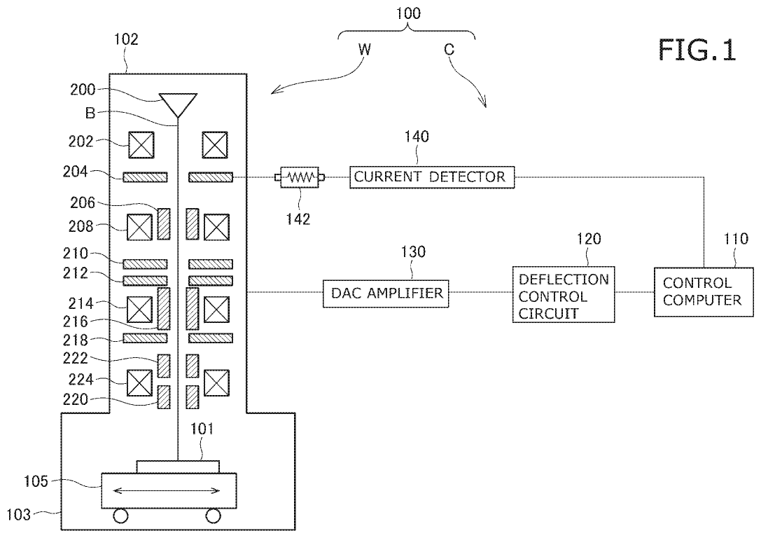

FIG. 1 is a schematic configuration diagram of a writing apparatus according to an embodiment of the present invention. As shown in FIG. 1, the writing apparatus 100 includes a writing unit W and a control unit C. The writing unit W includes an electron optical column 102, which is grounded, and a writing chamber 103. Within the electron optical column 102, an electron gun 200, a first illumination lens 202, a current limiting aperture substrate 204, a blanking deflector 206, a second illumination lens 208, a blanking aperture substrate 210, a first shaping aperture substrate 212, a projection lens 214, a shaping deflector 216, a second shaping aperture substrate 218, a main deflector 220, a sub-deflector 222, and an objective lens 224 are arranged. A sub-sub deflector may be further provided below the main deflector 220.

An XY stage 105 movable at least in the X and Y directions is disposed in the writing chamber 103. A substrate 101 to be written is placed on the XY stage 105. The substrate 101 includes, for example, an exposure mask for manufacturing a semiconductor device and a silicon wafer. The mask includes mask blanks.

The control unit C includes a control computer 110, a deflection control circuit 120, a digital-to-analog conversion (DAC) amplifier unit 130, a current detector 140, and the like. Although FIG. 1 shows one DAC amplifier unit 130, DAC amplifier units corresponding to respective deflectors, such as the blanking deflector 206, the shaping deflector 216, the main deflector 220, and the sub-deflector 222, are provided.

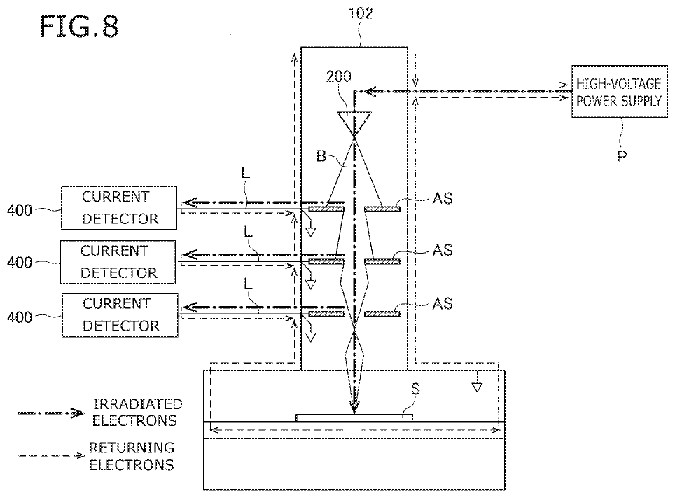

A high-voltage power supply circuit (see FIG. 8) is connected to the electron gun 200. By applying an acceleration voltage from the high-voltage power supply circuit between a filament (cathode) (not shown) and an extraction electrode (anode) in the electron gun 200, together with applying a voltage to another extraction electrode (Wehnelt) and heating the cathode, electrons emitted from the cathode are accelerated and emitted as an electron beam B.

The electron beam B emitted from the electron gun 200 (emission unit) travels while having a certain degree of divergence and irradiates the current limiting aperture substrate 204 having an opening by means of the first illumination lens 202. When the electron beam B passes through the opening of the current limiting aperture substrate 204, electrons (electron beam) in a peripheral region are blocked by the current limiting aperture substrate 204, and only electrons (electron beam) in a central region pass through the opening. The current limiting aperture substrate 204 limits the amount of the electron beam B passing therethrough. The current limiting aperture substrate 204 is a metal plate made of a non-magnetic, non-charging metal such as tantalum. The current limiting aperture substrate 204 has a rectangular shape in plan view, and a circular opening is formed at a central portion thereof. It is preferable that the center of the current limiting aperture substrate 204 coincides with the center of the circular opening.

The electron beam B that has passed through the current limiting aperture substrate 204 is controlled by the blanking deflector 206 so as to pass through the blanking aperture substrate 210 in a beam ON state, and is deflected such that the entire beam is blocked by the blanking aperture substrate 210 in a beam OFF state. A shot of the electron beam is defined as the electron beam B that passes through the blanking aperture substrate 210 from the time the beam changes from the beam OFF state to the beam ON state until it returns to the beam OFF state.

The blanking deflector 206 controls the trajectory of the passing electron beam B to alternately generate the beam ON state and the beam OFF state. For example, no voltage may be applied in the beam ON state, and a voltage may be applied to the blanking deflector 206 in the beam OFF state. The dose per shot of the electron beam B irradiated onto the substrate 101 is adjusted by the irradiation time of each shot.

As described above, each shot of the electron beam B generated by passing through the blanking deflector 206 and the blanking aperture substrate 210 irradiates a first shaping aperture substrate 212 having a rectangular opening by means of the second illumination lens 208. Here, the electron beam B is first shaped into a rectangular form.

Then, the electron beam B having an aperture image that has passed through the first shaping aperture substrate 212 is projected onto the second shaping aperture substrate 218 by the projection lens 214. The aperture image on the second shaping aperture substrate 218 is deflection-controlled by the shaping deflector 216, so that the beam shape and size can be varied. Such variable shaping is performed for each shot, and the beam is typically shaped into different shapes and sizes for each shot.

The electron beam B that has passed through the second shaping aperture substrate 218 is focused by the objective lens 224, deflected by the main deflector 220 and the sub-deflector 222, and irradiated onto a desired position on the substrate 101 placed on the continuously moving XY stage 105. As described above, a plurality of shots of the electron beam B are sequentially deflected onto the substrate 101 by the respective deflectors.

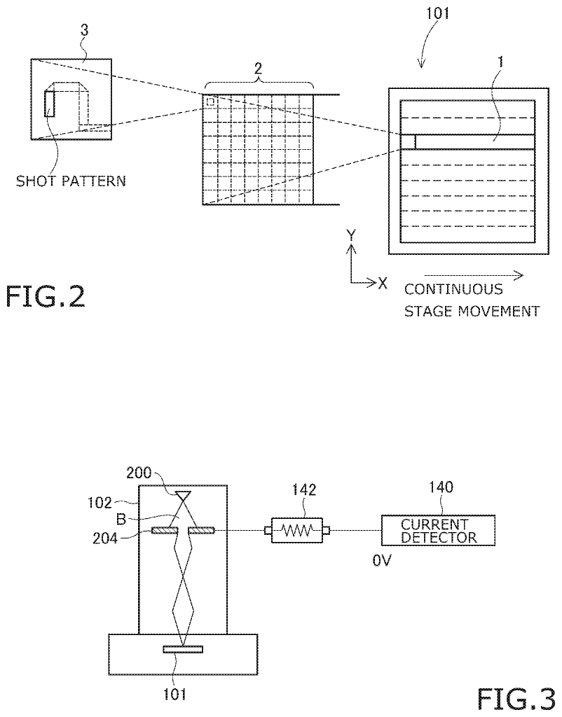

FIG. 2 is a conceptual diagram showing a main deflection region and a sub-deflection region. As shown in FIG. 2, when a desired pattern is written by the writing apparatus 100, a writing region of the substrate 101 is divided, for example in the Y direction, into a plurality of stripe-shaped writing regions (stripes) 1 each having a width that can be deflected by the main deflector 220. Each stripe 1 is further divided in the X direction with the same width as the width of the stripe in the Y direction. The divided regions constitute main deflection regions 2 that can be deflected by the main deflector 220. Regions obtained by further subdividing the main deflection region 2 are referred to as sub-deflection regions 3 (also called subfields).

The sub-deflector 222 is used to control the position of the electron beam B for each shot at high speed and with high accuracy. Therefore, the deflection range of the sub-deflector 222 is limited to the sub-deflection region 3, and deflection beyond that range is performed by the main deflector 220. The main deflector 220 is used to determine the sub-deflection region 3 to be written and performs beam deflection within a range (main deflection region 2) that includes a plurality of sub-deflection regions 3. Further, since the XY stage 105 continuously moves in the X direction during writing, the movement of the XY stage 105 can be followed by moving (tracking) the writing origin of the sub-deflection region 3 as needed with the main deflector 220.

The control computer 110 reads writing data from a storage unit (not shown) and generates shot data by performing multi-stage data conversion processing. The shot data includes information such as shot shape, shot size, shot position, and shot time.

The control computer 110 transfers the shot data to the deflection control circuit 120 in the order of shots. The deflection control circuit 120 outputs deflection signals for controlling deflection amounts of the blanking deflector 206, the shaping deflector 216, the main deflector 220, and the sub-deflector 222 using the shot data. The DAC amplifier unit 130 performs digital-to-analog conversion on the deflection signals output from the deflection control circuit 120, amplifies the signals, and outputs deflection voltages to be applied to the respective deflectors.

As described above, when the electron beam B passes through the opening formed in the current limiting aperture substrate 204, a portion of the electron beam B is blocked by the current limiting aperture substrate 204. In other words, a portion of the electron beam B is irradiated onto the current limiting aperture substrate 204. The current detector 140 detects a current value of the beam current irradiated onto (blocked by) the current limiting aperture substrate 204, and outputs a detection result to the control computer 110. The control computer 110 monitors, based on the detection result of the current detector 140, fluctuations in the beam current of the electron beam emitted from the electron gun 200 and occurrence of discharge within the electron optical column 102.

In the present embodiment, a resistor 142 is connected in series in wiring that connects the current limiting aperture substrate 204, having a circular opening at its center, and the current detector 140. Specifically, one end of the resistor 142 is connected to the current limiting aperture substrate 204 via wiring such as a coaxial cable, and the other end of the resistor 142 is connected to a terminal of the current detector 140 via wiring such as a coaxial cable.

Irradiated electrons incident on the current limiting aperture substrate 204 flow toward the current detector 140 via the wiring and the resistor 142. At this time, since the flow of electrons is opposite to the flow of current, the current flows from the current detector 140 toward the current limiting aperture substrate 204.

When a current flows from the current detector 140 toward the current limiting aperture substrate 204, a voltage drop occurs due to the resistor 142, and the current limiting aperture substrate 204 is at a lower potential than the current detector 140. As shown in FIG. 3, when the current detector 140 is operated at a ground potential (0 V), a negative potential (for example, −1 V) is applied to the current limiting aperture substrate 204.

When a negative potential is applied to the current limiting aperture substrate 204, secondary electrons emitted from the current limiting aperture substrate 204 are accelerated toward an upstream side with respect to a traveling direction of the electron beam and diffuse away from the beam trajectory. As a result, as compared with a case in which the aperture substrate AS is at the ground potential as shown in FIG. 8, the density of secondary electrons remaining on the beam trajectory is reduced. Therefore, the influence of the secondary electrons on the beam trajectory can be suppressed, and the accuracy of the beam irradiation position can be improved.

The resistance value of the resistor 142 is determined in accordance with a potential to be applied to the current limiting aperture substrate 204. In other words, by adjusting the resistance value of the resistor 142, a desired negative potential can be applied to the current limiting aperture substrate 204.

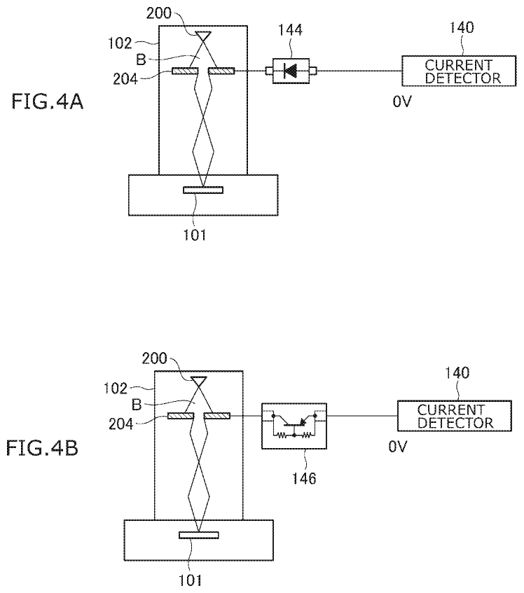

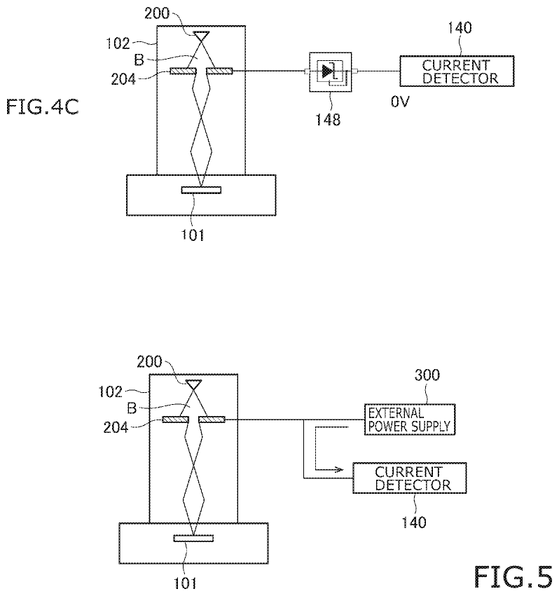

In the above embodiment, a configuration using the resistor 142 as a voltage drop element has been described; however, a semiconductor element such as a diode 144 shown in FIG. 4A, a voltage regulator circuit 146 including a transistor shown in FIG. 4B, or a shunt regulator 148 (or a Zener diode) shown in FIG. 4C may be used. By using such a semiconductor element, a constant negative potential can be applied to the current limiting aperture substrate 204. Characteristics of the semiconductor element to be used are determined in accordance with the potential to be applied to the current limiting aperture substrate 204.

As shown in FIG. 5, a configuration may be considered in which a negative potential is applied to the current limiting aperture substrate 204 using an external power supply 300. However, in such a configuration, current flows from the external power supply 300 to the current detector 140, making it difficult for the current detector 140 to accurately detect the beam current of the beam irradiated onto the current limiting aperture substrate 204.

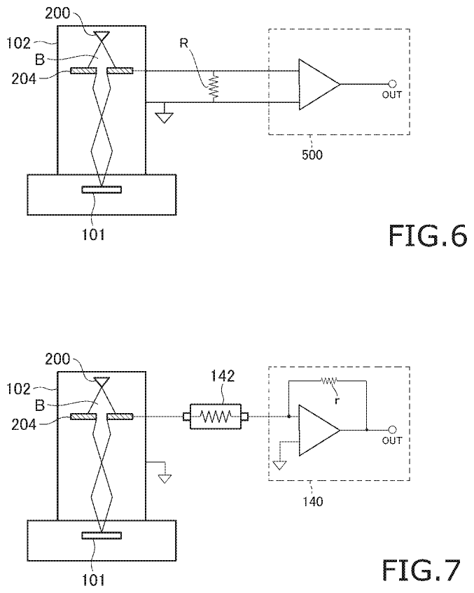

Further, as shown in FIG. 6, a configuration may be considered in which a voltage detector 500 is used to detect a voltage generated when the beam current of the beam irradiated onto the current limiting aperture substrate 204 flows through a resistor R connected to a common ground line. However, in such a configuration, although a negative potential is applied to the current limiting aperture substrate 204, the voltage detector 500 is more susceptible to noise in voltage detection. In other words, currents from other devices or circuits flowing through the common ground line cause noise to be superimposed on a measurement signal of the voltage detector, thereby preventing the voltage detector from accurately detecting the voltage. In addition, when voltage detection is employed, a semiconductor element cannot be used in place of the resistor R.

On the other hand, as shown in FIG. 7, in the present embodiment, while operating the current detector 140 at a ground potential (0 V), a resistor 142 (external resistor) is connected in series between the current limiting aperture substrate 204 and the current detector 140, separately from an internal resistance r of the current detector 140 for current detection, that is, while maintaining the function of the current detector. A voltage drop is thereby generated, and a negative potential is applied to the current limiting aperture substrate 204.

In the configuration shown in FIG. 7, even if the resistor 142 is omitted and a resistor R as shown in FIG. 6 is provided between the current limiting aperture substrate 204 and ground, since the current detector 140 operates at the ground potential and the resistor R is connected to ground, no voltage drop occurs in the wiring. Therefore, a negative potential cannot be applied to the current limiting aperture substrate 204.

In the above embodiment, a configuration has been described in which a negative potential is applied to the current limiting aperture substrate 204 disposed on the upstream side of the optical path relative to the blanking deflector 206. However, the same configuration can be applied to other aperture substrates provided in the electron optical column 102 that block a beam (or a portion thereof) and have a circular opening formed at the center. If the circular opening is formed at the center, no lens effect due to an electric field is exerted on the passing beam.

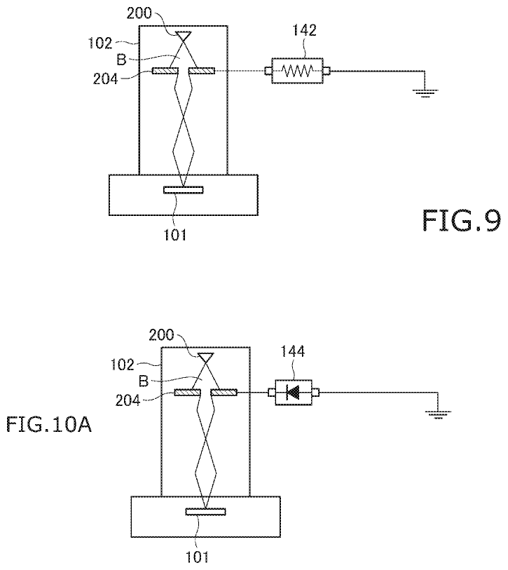

In the above embodiment, a configuration has been described in which one end of the resistor 142 is connected to the current limiting aperture substrate 204 and the other end of the resistor 142 is connected to the current detector 140 serving as a ground potential supply unit, thereby applying a negative potential to the current limiting aperture substrate 204. However, the ground potential supply unit is not limited to the current detector 140 that operates at the ground potential. As shown in FIG. 9, the current detector 140 may be omitted, and the other end of the resistor 142 may be connected to ground. Even in such a configuration, a voltage drop occurs due to the resistor 142, and a negative potential can be applied to the current limiting aperture substrate 204.

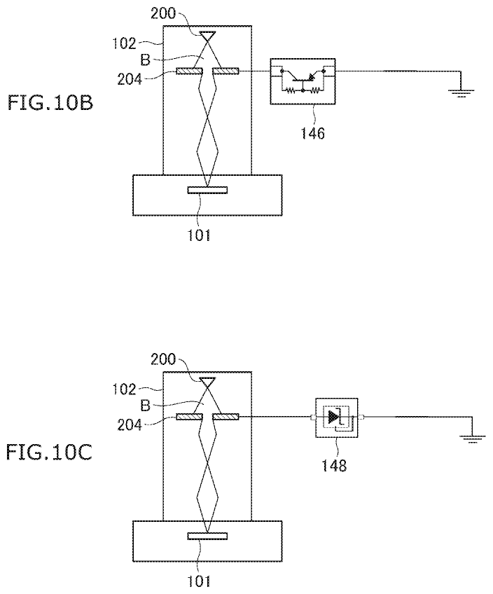

The voltage drop element is not limited to the resistor 142, and a semiconductor element such as a diode 144 shown in FIG. 10A, a voltage regulator circuit 146 including a transistor shown in FIG. 10B, or a shunt regulator 148 (or a Zener diode) shown in FIG. 10C may be used.

In the above embodiment, a single-beam writing apparatus has been described; however, the present invention is also applicable to a multi-beam writing apparatus.

Although the present invention has been described in detail with reference to specific embodiments, it will be apparent to those skilled in the art that various modifications can be made within the scope in which the effects of the invention are achieved.

### REFERENCE NUMERALS

100 Writing apparatus
101 Substrate
102 Electron optical column
103 Writing chamber
110 Control computer
140 Current detector
142 Resistor
204 Current limiting aperture substrate
206 Blanking deflector
210 Blanking aperture substrate

1. An electron beam writing apparatus comprising:
an emission unit configured to emit an electron beam;
an aperture substrate having an opening through which the electron beam passes and configured to block a part of the electron beam;
a deflector configured to deflect the electron beam having passed through the opening of the aperture substrate and to irradiate the electron beam onto a target substrate to write a pattern;
a wiring connected to the aperture substrate, through which a current based on the part of the electron beam blocked by the aperture substrate flows;
a ground potential supply unit connected to the wiring; and
a voltage drop element connected in series in the wiring connecting the aperture substrate and the ground potential supply unit, the voltage drop element being configured to apply a negative potential to the aperture substrate.

2. The electron beam writing apparatus according to claim 1, wherein the voltage drop element is a resistor.

3. The electron beam writing apparatus according to claim 1, wherein the voltage drop element is a semiconductor element.

4. The electron beam writing apparatus according to claim 3, wherein the semiconductor element is a diode or a voltage regulator circuit.

5. The electron beam writing apparatus according to claim 1, wherein a circular opening is formed at a center of the aperture substrate.

6. The electron beam writing apparatus according to claim 5, wherein the aperture substrate is a current limiting aperture substrate disposed upstream of a blanking deflector along an optical path.

7. An electron beam writing method comprising:
emitting an electron beam from an emission unit;
blocking a part of the electron beam by an aperture substrate when the electron beam passes through an opening of the aperture substrate;
deflecting, using a deflector, the electron beam having passed through the opening of the aperture substrate, and irradiating the electron beam onto a target substrate to write a pattern;
allowing a current based on the part of the electron beam blocked by the aperture substrate to flow through a wiring that connects the aperture substrate and a ground potential supply unit; and
applying a negative potential to the aperture substrate by causing the current to flow through a voltage drop element connected in series in the wiring.

8. The electron beam writing method according to claim 7, wherein the voltage drop element is a resistor.

9. The electron beam writing method according to claim 7, wherein the voltage drop element is a semiconductor element.

10. The electron beam writing method according to claim 9, wherein the semiconductor element is a diode or a voltage regulator circuit.
